(19) United States
(12) Patent Application Publication
(10) Pub. No.: US 2009/0267526 A1
(43) Pub. Date: Oct. 29, 2009

(54) ORGANIC LIGHT-EMITTING DIODE DISPLAY DEVICE

(75) Inventors: Si-Duk Sung, Seoul (KR); Joo-Woan Cho, Asan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/419,440

(22) Filed: Apr. 7, 2009

(30) Foreign Application Priority Data
Apr. 28, 2008 (KR) 2008-39450

(51) Int. Cl. G09G 3/10; F21V 29/00; H01J 1/63

(52) U.S. Cl. 315/169.3; 362/373; 313/504

(57) ABSTRACT

A display device includes a display panel, a power transmitting member and a heat diffusing member. The display panel includes a base substrate, a power input part, a power signal line and a display element. The base substrate has an upper surface and a lower surface opposite the upper surface. The power input part is formed in an outer peripheral area of the upper surface. The power signal line is electrically connected to the power input part. The display element is electrically connected to the power signal line and generates light based on a power signal transmitted via the power input part. The power transmitting member is electrically connected to the power input part to transmit the power signal to the power input part. The heat diffusing member is disposed on the lower surface, and includes a guide groove into which the power transmitting member is disposed.

This application claims priority to Korean Patent Application No. 2008-39450, filed on Apr. 28, 2008, and all the benefits accruing therefrom under 35 U.S.C. §119, the contents of which in its entirety are herein incorporated by reference.

### BACKGROUND OF THE INVENTION

1. Field of the Invention

The present invention relates to a display device. More particularly, the present invention relates to a display device including a self-emitting display element.

2. Description of the Related Art

Recently, there has been an increasing demand for lighter and/or thinner devices such as personal computers and television sets, for example. As a result, display devices included in such devices are also required to be made lighter and/or thinner. Thus, cathode ray tube (“CRT”) display devices are increasingly being replaced with lighter and/or thinner display devices, such as flat-panel display (“FPD”) devices, for example.

Examples of FPD devices include liquid crystal display (“LCD”) devices, field emission display (“FED”) devices, organic light-emitting diode (“OLED”) display devices and plasma display panel (“PDP”) display devices.

The OLED device, in particular, typically includes an organic light-emitting element, a driving transistor which drives the organic light-emitting element and a switching transistor which applies a data voltage to the driving transistor, for example. Transistors in the OLED device are generally formed as thin-film transistors (“TFTs”).

In operation, the organic light-emitting element receives a driving current via the driving transistor to generate light based on the driving current. In generating the light, the organic light-emitting element also generates heat. Thus, as a size of the OLED device increases, a required intensity of driving current applied to the OLED device increases, thereby causing an amount of heat generated by the organic light-emitting element to also increase. As a result, rapidly dissipating this heat generated in the OLED device is an increasingly important concern.

Specifically, when heat is not dissipated from near the organic light-emitting element or at a connection pad on which power lines are formed, for example, a hot spot is formed. Thus, a local temperature at the hot spot is high, relative to temperatures at other portions of the display panel. As a result, the organic light-emitting element is excessively heated, and a lifetime of the display panel is thereby reduced. In addition, the hot spots cause deterioration of a display quality of the display panel.

### BRIEF SUMMARY OF THE INVENTION

Exemplary embodiments of the present invention provide a display device which effectively prevents damage thereto due to nonuniform temperatures, e.g., hot spots, as well as having substantially improved ease of assembly and physical rigidity.

According to an exemplary embodiment of the present invention, a display device includes a base substrate, a power input part, a power signal line, a display element and a heat diffusing member.

The base substrate has an upper surface and a lower surface opposite the upper surface. The power input part is disposed in the upper surface of the base substrate. The power signal line is electrically connected to the power input part. The display element is electrically connected to the power signal line. The display element generates light based on a power signal transmitted via the power input part. The heat diffusing member is disposed on the lower surface of the base substrate. The heat diffusing member has a guide groove.

The display device may further include a power transmitting member. The power transmitting member is electrically connected to the power input part and disposed in the guide groove.

The heat diffusing member is disposed on the lower surface of the base substrate, and has a guide groove into which the power transmitting member is disposed.

The heat diffusing member may include a first surface facing the lower surface of the base substrate and a second surface opposite to the first surface. The guide groove may be formed in the second surface of the heat diffusing member. A depth of the guide groove may be less than a thickness of the heat diffusing member. In addition, the depth of the guide groove may be greater than or equal to a thickness of the power transmitting member. A cross-sectional shape of the guide groove may correspond to a cross-sectional shape of the power transmitting member.

The heat diffusing member may include a graphite plate. Alternatively, the heat diffusing member may include a metal plate. The display device may further include an adhesive layer interposed between the lower surface of the base substrate and the first surface of the heat diffusing member.

The display device may further include a receiving frame configured to receive the display panel, the power transmitting member and the heat diffusing member. In this case, the receiving frame makes contact with the second surface of the heat diffusing member.

The display element may include a first electrode, a second electrode facing the first electrode and an organic light-emitting layer disposed therebetween. The power signal may include a driving voltage and a common voltage. The driving voltage is applied to the first electrode. The common voltage is applied to the second electrode. The organic light-emitting layer generates light using a current flowing between the first electrode and the second electrode.

The power signal line may include a driving voltage line and a common voltage line. The driving voltage line transmits the driving voltage to the first electrode. The common voltage line crosses the driving voltage line and transmits the common voltage to the second electrode.

The power transmitting member may include at least one driving voltage transmitting member which transmits the driving voltage to the first electrode and at least one common voltage transmitting member which transmits the common voltage to the second electrode.

The guide groove may include a first groove and a second groove. The driving voltage transmitting member is disposed in the first groove. The common voltage transmitting member is disposed in the second groove.

The outer peripheral area of the upper surface of the base substrate includes an upper peripheral area, a lower peripheral area facing the upper peripheral area, a left peripheral area connecting the upper peripheral area and the lower peripheral area, and a right peripheral area facing the left peripheral area and connecting the upper peripheral area and the lower peripheral area. The power input part may include a first connection pad and a second connection pad. The first connection pad connects the driving voltage line to the driving voltage transmitting member and is disposed in one of the upper peripheral area and the lower peripheral area. The second connection pad connects the common voltage line to the common voltage transmitting member and is disposed in one of the left peripheral area and the right peripheral area. The first groove extends to an upper peripheral edge of the heat diffusing member to form a first opening at the upper peripheral edge thereof The driving voltage transmitting member extends outward from the heat diffusing member through the first opening to connect to the first connection pad. The second groove extends to one of a right peripheral edge and a left peripheral edge of the heat diffusing member to form a second opening at the one of the right peripheral edge and the left peripheral edge thereof The common voltage transmitting member extends outward from the heat diffusing member through the second opening to connect to the second connection pad.

The display panel may further include a driving signal line and a driving element. The driving signal line transmits a driving signal for controlling the driving voltage. The driving element is connected to the driving signal line and the driving voltage line to transmit the driving voltage to the first electrode based on the driving signal.

The driving signal line may extend to the upper peripheral area on the base substrate, and the driving module comprises, the display device may further include a driving module. The driving module may include a driving substrate and a connection printed circuit film. The driving substrate outputs the driving signal. The connection printed circuit film connects the driving substrate to the driving signal line in the upper peripheral area.

The driving voltage transmitting member is connected to a driving voltage connector formed on the driving substrate. The driving voltage transmitting member receives the driving voltage through the driving substrate via the driving voltage connector. The common voltage transmitting member is coupled to a common voltage connector formed on the driving substrate. The driving voltage transmitting member receives the common voltage through the driving substrate via the common voltage connector.

The driving signal line may include a data line and a gate line. The data line may be formed substantially parallel to the driving voltage line and may transmit a data signal. The gate line may be formed substantially parallel with the common voltage line and may transmit a scan signal.

The driving element may include a switching transistor and a driving transistor. The switching transistor may include a source electrode connected to the data line, a gate electrode connected to the gate line and a drain electrode which outputs the data signal. The driving transistor may include a control terminal connected to the drain electrode of the switching transistor, an input terminal connected to the driving voltage line and an output terminal connected to the first electrode.

The driving module may further include a gate driving section. The gate driving section is connected to the gate line in one of the left peripheral area and the right peripheral area of the base substrate to output the scan signal to the gate line.

The display panel may further include a display plate. The display plate faces the base substrate, is coupled thereto, and covers the display element. An image is displayed on the display plate using light emitted from the organic light-emitting layer.

According to exemplary embodiments of the present invention, the display device has advantages which include, but are not limited to, thermal diffusion of heat by the diffusing member resulting in improved temperature uniformity at different locations of the display panel. As a result, damage caused by hot spots is substantially reduced and/or effectively prevented. In addition, the power transmitting member is received in the guide groove of the heat diffusing member, and a thickness of the display device is thereby substantially reduced. Further, the heat diffusing member substantially enhances a rigidity of the display panel, thereby protecting the display panel from damage resulting from external impact.

### BRIEF DESCRIPTION OF THE DRAWINGS

The above and other aspects, features and advantages of the present invention will become more readily apparent by describing in further detail exemplary embodiments thereof with reference to the accompanying drawings, in which:

FIG. 1 is a perspective view of a display device according to an exemplary embodiment of the present invention;

FIG. 2 is an exploded perspective view of the display device according to the exemplary embodiment of the present invention shown in FIG. 1;

FIG. 3 is a block diagram of the display device according to the exemplary embodiment of the present invention shown in FIG. 2;

FIG. 4 is an equivalent circuit diagram of a pixel of the display device according to the exemplary embodiment of the present invention shown in FIG. 3;

FIG. 5 is a partial cross-sectional view of a display element and a driving element of the display device according to the exemplary embodiment of the present invention shown in FIG. 4;

FIG. 6 is a perspective view a heat diffusing member of the display device according to the exemplary embodiment of the present invention shown in FIG. 2;

FIG. 7 is a partial cross-sectional view taken along line I-I′ of FIG. 2;

FIG. 8 is a plan view of a front surface of a display panel of the display device according to the exemplary embodiment of the present invention shown in FIG. 2;

FIG. 9 is a plan view of a rear surface of the display panel of the display device according to the exemplary embodiment of the present invention shown in FIG. 8;

FIG. 10 is a graph of temperature versus location illustrating a temperature distribution in a display panel not having a heat diffusing member; and

FIG. 11 is a graph of temperature versus location illustrating a temperature distribution of the display panel of the display device according to the exemplary embodiment of the present invention shown in FIG. 8.

### DETAILED DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

Hereinafter, exemplary embodiments of the present invention will be described in further detail with reference to the accompanying drawings.

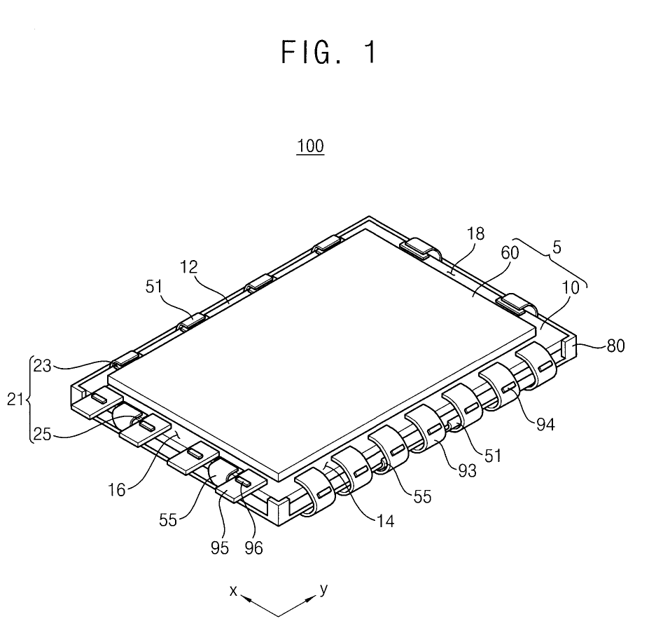

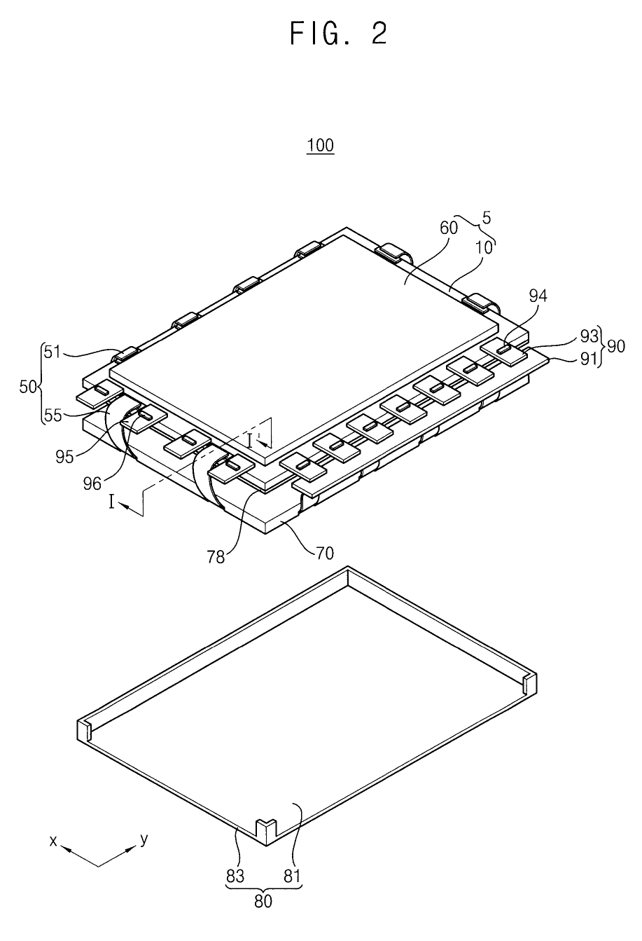

FIG. 1 is a perspective view of a display device according to an exemplary embodiment of the present invention. FIG. 2 is an exploded perspective view of the display device according to the exemplary embodiment of the present invention shown in FIG. 1.

Referring to FIGS. 1 and 2, a display device 100 according to an exemplary embodiment of the present invention includes a display panel 5, a power transmitting member 50 and a heat diffusing member 70.

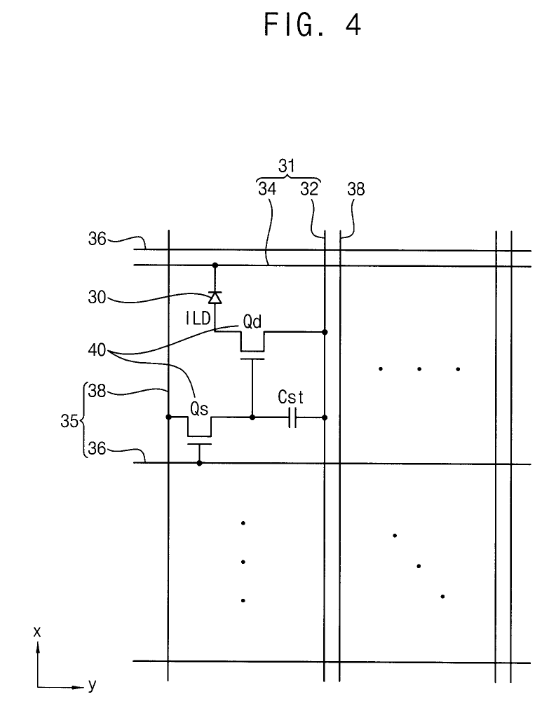

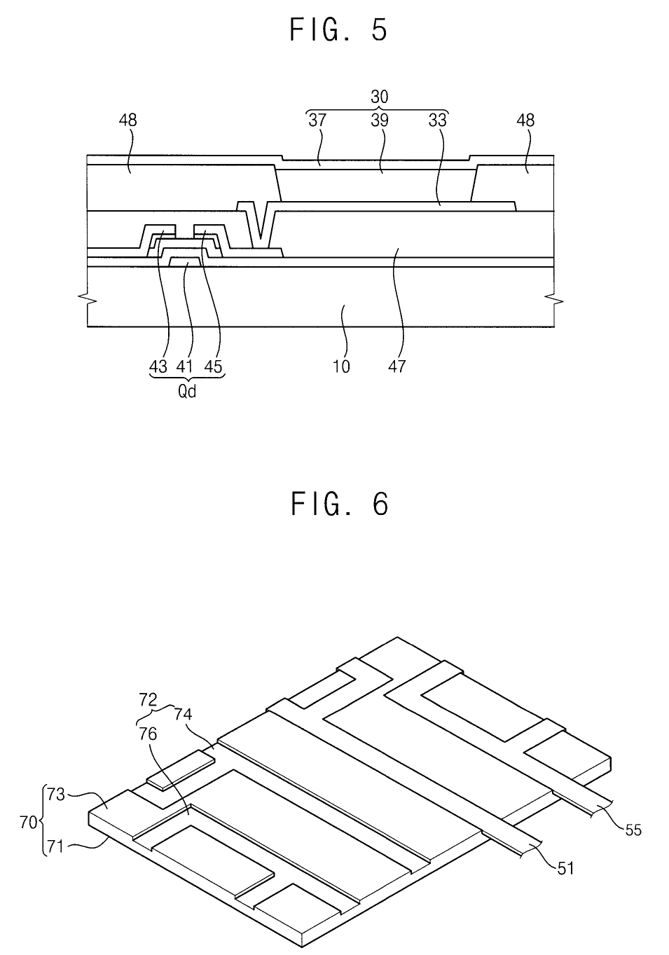

The display panel 5 receives a power signal from the power transmitting member 50 to display information, e.g., an image, thereon. The display panel 5 includes a base substrate 10, a power input part 21, a display element 30 (FIGS. 4 and 5) and a power signal line 31 (FIGS. 4 and 5).

In an exemplary embodiment of the present invention, the base substrate 10 may include glass, for example, but alternative exemplary embodiments are not limited thereto. In addition, the base substrate 10 may have a substantially rectangular, e.g., plate, shape. In this case, the base substrate 10 has opposite long (longitudinal) sides facing each other and opposite short (latitudinal) sides facing each other to form the rectangular shape. A display area and a peripheral area are defined on an upper surface of the base substrate 10. Specifically, the peripheral area corresponds to a peripheral portion of the display area, e.g., the peripheral area is disposed around an outer periphery of the rectangular shape, substantially surrounding the display area within the opposite longitudinal and latitudinal sides. More specifically, as shown in FIG. 1, separate peripheral areas, corresponding to the long sides, will hereinafter be referred to as an upper peripheral area 12 and a lower peripheral area 14. Likewise, separate peripheral areas corresponding to the short sides will hereinafter be referred to as a left peripheral area 16 and a right peripheral area 18. The upper peripheral area 12, the lower peripheral area 14, the left peripheral area 16 and the right peripheral area 18 will hereinafter be referred to, collectively or in part, as a “peripheral area” or “peripheral areas”.

The power input part 21 is formed in the peripheral area. The power input part 21 according to an exemplary embodiment may include a first connection pad 23 and a second connection pad 25. In addition, a plurality of the first connection pads 23 may be formed in the upper peripheral area 12. Similarly, a plurality of the second connection pads 25 may be formed in the left peripheral area 16 and/or in the right peripheral area 18. During operation of the display device 100, a power signal from an external source (not shown) is applied to the first connection pad 23 and the second connection pad 25.

More particularly, the power signal may include a driving voltage, applied to the first connection pad 23, and a common voltage, applied to the second connection pad 25.

The display device 100 may further include a receiving frame 80, as shown in FIG. 2.

In an exemplary embodiment, the receiving frame 80 receives the display panel 5, the power transmitting member 50 and the heat diffusing member 70. Further, the receiving frame 80 may include a metal material to dissipate heat. The receiving frame 80 may include a bottom plate 81 and a sidewall 83. The bottom plate 81 according to an exemplary embodiment of the present invention may have a substantially rectangular shape corresponding to a shape of the display panel 5. Sidewalls 83 extend from respective peripheral edges of the bottom plate 81. In addition, a portion of one or more of the sidewalls 83 may be cut, e.g., partially removed, to facilitate receiving the display panel 5, the power transmitting member 50 and the heat diffusing member 70, as shown in FIG. 2.

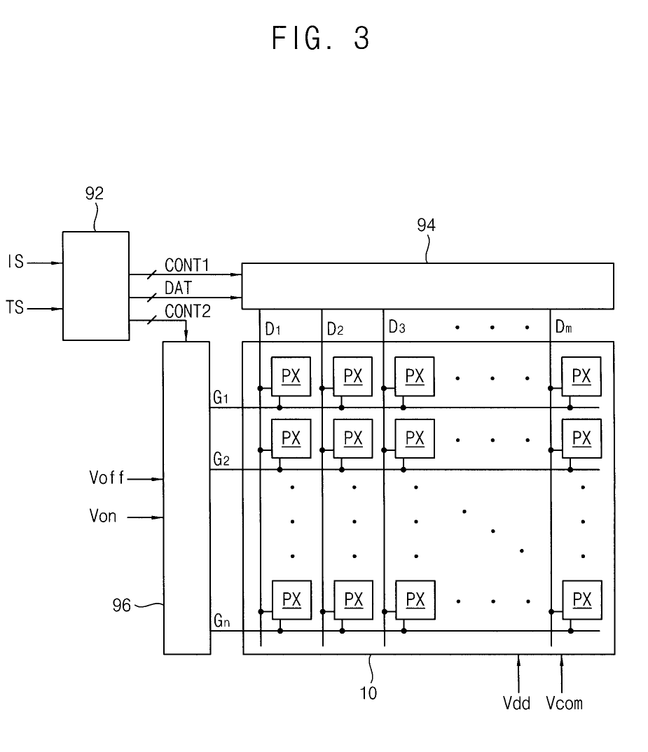

FIG. 3 is a block diagram of the display device 100 according to the exemplary embodiment of the present invention shown in FIG. 2. FIG. 4 is an equivalent circuit diagram of one pixel PX of the display device 100 according to the exemplary embodiment of the present invention shown in FIG. 3.

Referring to FIGS. 3 and 4, a power signal line 31 includes a driving voltage line 32 which transmits a driving voltage Vdd and a common voltage line 34 which transmits a common voltage Vcom.

Individual driving voltage lines 32 of a plurality of the driving voltage lines 32 extend in an upper-lower direction, e.g., a vertical direction as viewed in FIGS. 1 and 2, (hereinafter referred to as a column direction ‘x’), and are spaced apart from and substantially in parallel with each other. End portions of the driving voltage lines 32 extend into the upper peripheral area 12 and are connected to the first connection pad 23 (FIG. 1). Each driving voltage line 32 electrically connects the display element 30 and the first connection pad 23. Common voltage lines 34 of a plurality of the common voltage lines 34 extend in a left-right direction, e.g., a horizontal direction as viewed in FIGS. 1 and 2, (hereinafter referred to as a row direction ‘y’), and are spaced apart from and substantially in parallel with each other. End portions of the common voltage lines 34 extend to the left peripheral area 16 and/or the right peripheral area 18 and are connected to the second connection pad 25, as illustrated in FIG. 1. Each common voltage line 34 electrically connects the display element 30 and the second connection pad 25.

The display panel 5 may further include a driving signal line 35 and a driving element 40. In an exemplary embodiment, the display panel 5 may be driven in a passive-type manner, e.g., a manner in which the driving signal line 35 and the driving element 40 are not required, or may be driven in an active-type manner, e.g., each pixel PX includes and associated driving signal line 35 and driving element 40 connected thereto.

The driving element 40 receives a driving signal through the driving signal line 35. The driving element 40 controls the driving voltage Vdd applied to the display element 30 based on the driving signal. In an exemplary embodiment of the present invention, the driving signal may include a scan signal and/or a data voltage. The driving signal line 35 may include a plurality of gate lines 36, through which the scan signal is transmitted, and a plurality of data lines 38, through which the data voltage is transmitted.

Individual gate G₁ through Gₙ (FIG. 3) of the plurality of gate lines 36 (FIG. 4) extend substantially in parallel with the common voltage line 34, e.g., in the row direction y, and are substantially parallel with and spaced apart from each other by a predetermined interval. Individual data lines D₁ through Dₘ (FIG. 3) of the plurality of data lines 38 (FIG. 4) extend substantially in parallel with the driving voltage line 32, e.g., in the column direction x, and are substantially parallel with and spaced apart from each other by a predetermined interval.

FIG. 5 is a partial cross-sectional view of display element and a driving element of the display device according to the exemplary embodiment of the present invention shown in FIG. 4.

Referring to FIGS. 4 and 5, the driving element 40 is formed on an upper surface of the base substrate 10. The driving element 40 includes a switching transistor Qs and a driving transistor Qd. In an exemplary embodiment of the present invention, the switching transistor Qs and driving transistor Qd may be thin-film transistors (“TFTs”).

The switching transistor Qs may include a source electrode connected to the data line 38, a gate electrode connected to the gate line 36 and a drain electrode which outputs the data signal.

As shown in FIG. 5, the driving transistor Qd may include a control terminal 41 connected to the drain electrode of the switching transistor Qs (FIG. 4), an input terminal 43 connected to the driving voltage line 32 and an output terminal 45 which outputs the driving voltage Vdd to the display element 30.

A capacitor Cst is connected to the drain electrode of the switching transistor Qs and the driving voltage line 32. During operation, the capacitor Cst charges to maintain the data voltage, supplied to the display element 30 from the switching transistor Qs, for a predetermined duration of time.

In an exemplary embodiment of the present invention, the display element 30 may be formed on a protective layer 47 covering the driving element 40. Further, the display element 30 may include a first electrode 33, a second electrode 37 and an organic light-emitting layer 39, as shown in FIG. 5.

The first electrode 33 is connected to the output terminal 45 of the driving transistor Qd to receive the driving voltage Vdd, which is controlled based on the data voltage.

The second electrode 37 is disposed over the first electrode 33 and opposite to, e.g., facing, the first electrode 33. The second electrode 37 is connected to the common voltage line 34 to receive the common voltage Vcom. The organic light-emitting layer 39 is disposed between the first electrode 33 and the second electrode 37.

Thus, the organic light-emitting layer 39 is disposed in a pixel area, defined by a partition pattern 48 formed on the protective layer 47. In an exemplary embodiment of the present invention, the organic light-emitting layer 39 may include organic materials which generate red, green and blue colors in respective pixels, or an organic material which generates a white color. More specifically, the organic light-emitting layer 39 generates light having a variable intensity based on an amount of current ILD (FIG. 4) flowing between the first electrode 33 and the second electrode 37. As a result, an image is displayed on the display device 100.

During operation, the organic light-emitting layer 39 generates heat while generating the light to display the image. It is advantageous to dissipate the heat and, therefore, in an exemplary embodiment of the present invention, the heat is externally dissipated and/or diffused by the heat diffusing member 70 (FIG. 2), as will be described in greater detail below.

Referring again to FIGS. 1 and 2, the power transmitting member 50 applies the externally applied power signal, e.g., the driving voltage Vdd and the common voltage Vcom, to the display panel 5. In an exemplary embodiment, the power transmitting member 50 is a flexible printed circuit film. In addition, the power transmitting member 50 may include a driving voltage transmitting member 51 and a common voltage transmitting member 55, as shown in FIGS. 1 and 2.

The driving voltage Vdd is applied from an external device (not shown) to an input terminal of the driving voltage transmitting member 51. An output terminal of the driving voltage transmitting member 51 is connected to the first connection pad 23 formed in the upper peripheral area 12. Therefore, the driving voltage lines 32 according to an exemplary embodiment of the present invention correspond to the first connection pads 23, and output terminals of a plurality of the driving voltage transmitting members 51 are connected to the first connection pads 23.

The common voltage Vcom is applied from an external source (not shown) to an input terminal of the common voltage transmitting member 55. An output terminal of the common voltage transmitting member 55 is connected to the second connection pad 25 formed in the left peripheral area 16 and/or the right peripheral area 18. Thus, the common voltage Vcom, as illustrated in FIG. 2, may be provided through left peripheral area 16 and the right peripheral area 18. As a result, voltage differences based on location through which the common voltage is applied, are effectively prevented, e.g., a uniformity of the common voltage Vcom is substantially enhanced throughout the display device 100 according to an exemplary embodiment.

The driving voltage lines 32 and the common voltage lines 34 are formed proximate to the first connection pad 23, the second connection pad 25 and circumferential portions thereof As a result, heat is uniformly generated around the first connection pad 23 and the second connection pad 25. Specifically, heat is generated and remains proximate to the circumferential portions of each of the first connection pad 23 and the second connection pad 25. As a result, hot spots in which a relatively high temperature is maintained in comparison with other portions are generated proximate to the circumferential portions of the first connection pad 23 and the second connection pad 25. Therefore, the display element 30, disposed at the circumferential portions of the first connection pad 23 and the second connection pad 25 is heated. As a result, a lifetime of the display element is decreased. In addition, a display quality of the display device 100 is reduced if the heating of the display element 30 is not reduced, as will be described in further detail below.

FIG. 6 is a perspective view of a rear surface of a heat diffusing member of the display device according to the exemplary embodiment of the present invention shown in FIG. 2.

Referring to FIGS. 2 and 6, the heat diffusing member 70 is disposed on a lower surface of the base substrate 10. The heat diffusing member 70 dissipates heat generated from the display panel 5. Specifically, the heat diffusing member 70 diffuses the heat in both a vertical direction and a horizontal direction relative to a thickness of the base substrate 10.

Thus, heat does not concentrate in any specific locations of the display panel 5 according to an exemplary embodiment of the present invention, and a temperature uniformity of the display panel 5 is thereby substantially improved. As a result, the overall temperature of the display panel 5 is also reduced, thereby preventing the detrimental heating of the display element 30 described above.

In addition, the heat diffusing member 70 protects the base substrate 10 from external impact, since the heat diffusing member 70 improves an overall rigidity of the display device 100 according to an exemplary embodiment of the present invention.

In an exemplary embodiment of the present invention, the heat diffusing member 70 may include a graphite plate having adequate thermal conductivity, or, alternatively, a metal plate such as an aluminum plate or a copper plate, for example, but alternative exemplary embodiments are not limited thereto.

Specifically, the graphite plate according to an exemplary embodiment of the present invention has a thermal conductivity of approximately 5 W/mK to approximately 10 W/mK in a thickness direction of the graphite plate, and a thermal conductivity of approximately 100 W/mK to approximately 400 W/mK in a horizontal direction thereof (e.g., in a direction substantially perpendicular to the thickness direction). Put another way, the graphite plate has a great thermal conductivity in the horizontal direction (relative to the thickness direction thereof) to effectively prevent formation of the above-mentioned detrimental hot spots.

In alternative exemplary embodiments of the present invention, the aluminum plate has an isotropic thermal conductivity of approximately 220 W/mK, while the copper plate has an isotropic thermal conductivity of approximately 380 W/mK. Thus, the heat diffusing member 70 such as the aluminum plate and the copper plate are still effective in heat dissipation and thermal diffusion, and are therefore effective in preventing formation of the detrimental hot spots described above.

The heat diffusing member 70 includes a first surface 71 facing the lower surface of the base substrate 10 and a second surface 73 opposite to the first surface 71. In addition, a guide groove 72 is formed at the second surface 73 to reduce a thickness of portions of the display device 100. As a result, a compactness of the display device 100 is substantially enhanced. The guide groove 72 may be formed on the graphite plate, or, alternative, the metal plate using a mold, for example.

The power transmitting member 50 is received in and guided by the guide groove 72. Thus, the guide groove 72 may have a shape substantially corresponding to a shape of the power transmitting member 50, and may further be patterned on the second surface 73 of the heat diffusing member 70. Thus, the pattern of the guide groove 72 may vary based on the shape of the power transmitting member 50.

The guide groove 72 is open at a side of the heat diffusing member 70. Further, the guide groove 72 has a depth smaller than a thickness of the heat diffusing member 70. Thus, the heat diffusing member 70 is not open in the thickness direction, and heat is more efficiently diffused therethrough. In an exemplary embodiment of the present invention, the depth of the guide groove 72 may be greater than or equal to a depth of the power transmitting member 50. Thus, the power transmitting member 50 may be completely disposed in the guide groove 72.

The guide groove 72 may include a first groove 74 and a second groove 76, as shown in FIG. 6. In this case, the driving voltage transmitting member 51 extends through a portion of the first groove 74 at an edge of the peripheral area and which is open to an upper side, e.g., in the upper peripheral area 12, of the heat diffusing member 70, and connected to the first connection pad 23 therethrough. In a similar manner, the common voltage transmitting member 55 protrudes through a portion of the second groove 76 at an edge of the peripheral area which is open to a left side and/or a right side of the heat diffusing member 70, e.g., at the left peripheral area 16 and/or the right peripheral area 18, respectively, and is thereby connected to the second connection pad 25.

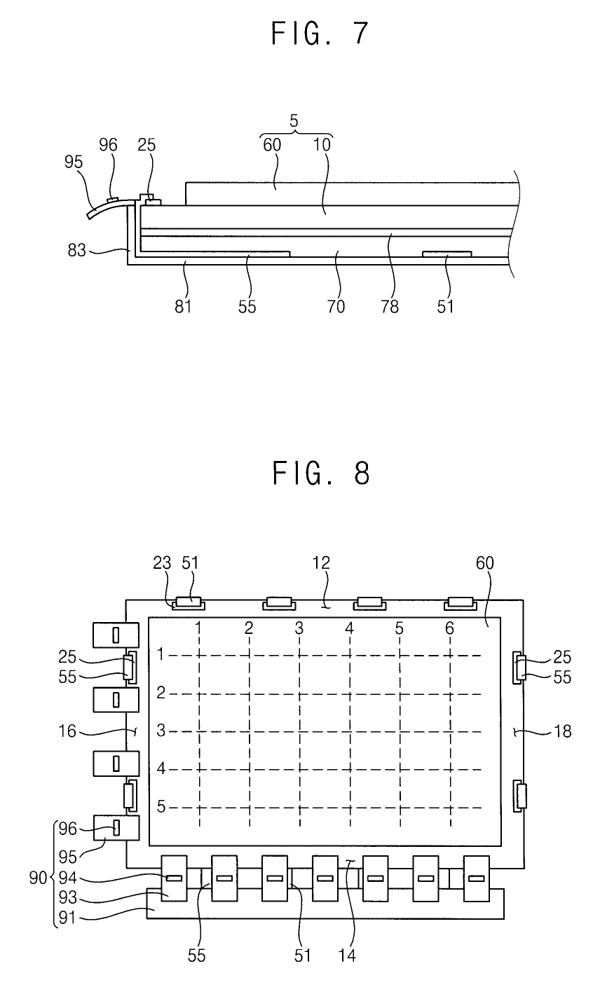

FIG. 7 is a partial cross-sectional view taken along line I-I′ FIG. 2.

Referring to FIGS. 1, 2 and 7, the heat diffusing member 70 and the display panel 5 are disposed on the bottom plate 81 of the receiving frame 80.

The display device 100 according to an exemplary embodiment of the present invention may further include an adhesive layer 78. In this case, the adhesive layer 78 is interposed between the lower surface of the base substrate 10 and the first surface 71 of the heat diffusing member 70. Alternatively, the heat diffusing member 70 may be formed by coating a heat diffusing material (not shown) on the lower surface of the base substrate 10.

In an exemplary embodiment, the power transmitting member 50 is entirely received in the guide groove 72 formed at the heat diffusing member 70, as described in greater detail above. Thus, the power transmitting member 50 does not prevent sufficient contact between the bottom plate 81 and the second surface 73 of the heat diffusing member 70, e.g., the power transmitting member 50 does not significantly reduce a heat transfer capability between the bottom plate 81 and the second surface 73 of the heat diffusing member 70.

Thus, the second surface 73 of the heat diffusing member 70 makes close contact with the bottom plate 81, and heat is effectively dissipated from the heat diffusing member 70 to the receiving frame 80. In addition, a thickness of the display device 100 is substantially, since a thickness of the power transmitting member 50 is reduced due to the guide groove 72.

In an exemplary embodiment of the present invention, the display panel 5 may further include a display plate 60. Further, the display plate 60 may include a glass substrate, for example, but alternative exemplary embodiments are not limited thereto. The display plate 60 is coupled to, e.g., connected to, the base substrate 10 to face the base substrate 10, and thereby covers at least a portion of the display elements 30. A sealing member (not shown) may be disposed between the base substrate 10 and the display plate 60, e.g., in an area substantially corresponding to the peripheral area. Information, e.g., an image, is then displayed on the display plate 60 using light emitted from the organic light-emitting layer 39.

FIG. 8 is a plan view of a front surface of the display panel of the display device according to the exemplary embodiment of the present invention shown in FIG. 2.

Referring to FIGS. 2, 3 and 8, the display device 100 according to an exemplary embodiment may further include a driving module 90. The driving module 90 transmits the driving signal which controls the driving voltage Vdd to the display panel 5. The driving module 90 may include a driving substrate 91 and a data connection printed circuit film 93.

The driving substrate 91 may be disposed in an area substantially corresponding to the lower peripheral area 14, as shown in FIG. 8. The driving substrate 91 may further include a signal control section (not shown). In an exemplary embodiment of the present invention, the signal control section receives signals from an external device or source (not shown). The signals may include an original image signal IS and a timing signal TS to output a first control signal CONT1 and a second control signal CONT2 which the driving signal and an image signal DAT, respectively.

The data connection printed circuit film 93 connects the driving substrate 91 to the data line 38 extending into the lower peripheral area 14.

The driving module 90 may further include a data driving section 94 disposed on the data connection printed circuit film 93 in a tape carrier package (“TCP”) type configuration. The data driving section 94 receives the first control signal CONT1 and the image signal DAT through the data connection printed circuit film 93, and applies the data voltage to the data line 38.

The driving module 90 may further include a gate driving section 96 and a gate connection printed circuit film 95.

The gate connection printed circuit film 95 is connected to the gate line 36 extending into the left peripheral area 16 and/or the right peripheral area 18.

The gate driving section 96 is mounted on the gate connection printed circuit film 95 in a TCP type configuration, and receives a gate on voltage Von and a gate off voltage Voff from an external source (not shown). The gate driving section 96 also receives the second control signal CONT2 through the gate connection printed circuit film 95, and outputs the scan signal to the gate line 36.

In an alternative exemplary embodiment of the present invention, the gate driving section 96 and the data driving section 94 may be directly mounted on and/ or integrated onto the lower peripheral area 14 and the left peripheral area 16 (or, alternatively, the right peripheral area 18) in an integrated circuit (“IC”) chip form. Alternatively, the data driving section 94 and the signal control section may be integrated into one chip.

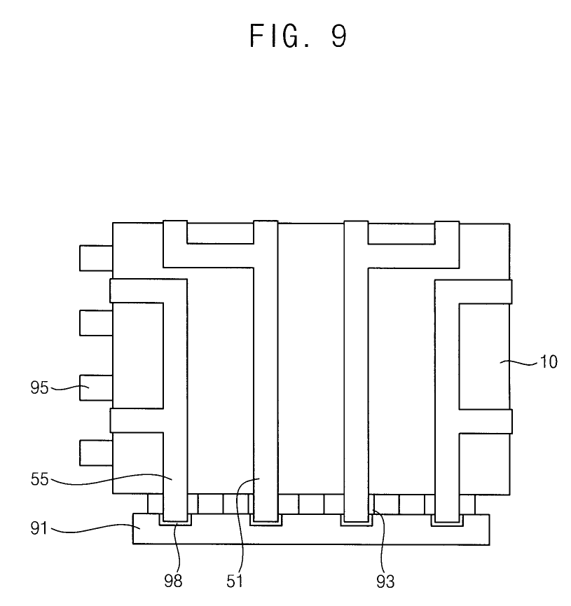

FIG. 9 is a plan view of a rear surface of the display panel of the display device according to the exemplary embodiment of the present invention shown in FIG. 8.

Referring now to FIG. 9, the power transmitting member 50 is connected to the driving substrate 91 and receives the power signal through the driving substrate 91. Thus, a plurality of connectors 98 may be formed on a lower surface or a side surface of the driving substrate 91.

In this case, input terminals of the driving voltage transmitting members 51 are connected to driving voltage connectors 98. Therefore, the driving voltage transmitting members 51 are received in and guided by the first grooves 74 formed in a substantially central area of the heat diffusing member 70. Each driving voltage transmitting member 51 is divided into a plurality of branches, and output terminals formed at end portions of each of the branches extend substantially along the upper side of the heat diffusing member 70 and are thereby connected to the first connection pad 23 of the display panel 5, as shown in FIG. 8.

Similarly, the input terminals of the common voltage transmitting member 55 are connected to common voltage connectors 98. The common voltage transmitting members 55 are received in and guided by the second grooves 76 formed at left and/or right edges, e.g., in the left peripheral area 16 and/or the right peripheral area 18, respectively, of the heat diffusing member 70. Each common voltage transmitting member 55 is divided into a plurality of branches, and output terminals formed at end portions of each of the branches extend substantially along the left and right sides of the heat diffusing member 70 and are thereby connected to the second connection pad 25 of the display panel 5, as shown in FIG. 8.

Thus, the data connection printed circuit film 93, the driving voltage transmitting member 51 and the common voltage transmitting member 55 extend to an outer side surface 83 of the receiving frame 80, and the driving substrate 91 is thereby disposed on a rear surface of the bottom plate 81 of the receiving frame 80.

For purposes of comparison a display device 100 according to an exemplary embodiment of the present invention as described in FIGS. 1 through 8 was manufactured, and a test display device the same as the display device 100 described in FIGS. 1 through 8 except that the test display device did not include the heat diffusing member 70 was also manufactured to conduct a comparative experiment. Specifically, the experiment compared between the heat dissipation capabilities of the display device 100 (according to an exemplary embodiment of the present invention) to the heat dissipation capabilities of the test display device (not having the heat diffusing member 70).

In the experiment, the display device 100 and the test display device (excluding the heat diffusing member 70) both included a display panel 5 having a size of approximately 14.1 inches. The display device 100 and the test display device excluding the heat diffusing member 70 were both driven for approximately 2 hours in a full white display mode, and a temperature distribution for each was measured at a plurality of points of each display screen of the display panel 5.

As shown in FIG. 8, each display screen was divided into measurement areas forming a matrix having five rows (1-5) and six columns (1-6) to use as locations for measuring temperatures. In addition, a maximum temperature was measured for each measurement area in the matrix.

FIG. 10 is a graph of temperature versus location illustrating a temperature distribution in the display panel (without a heat diffusing member).

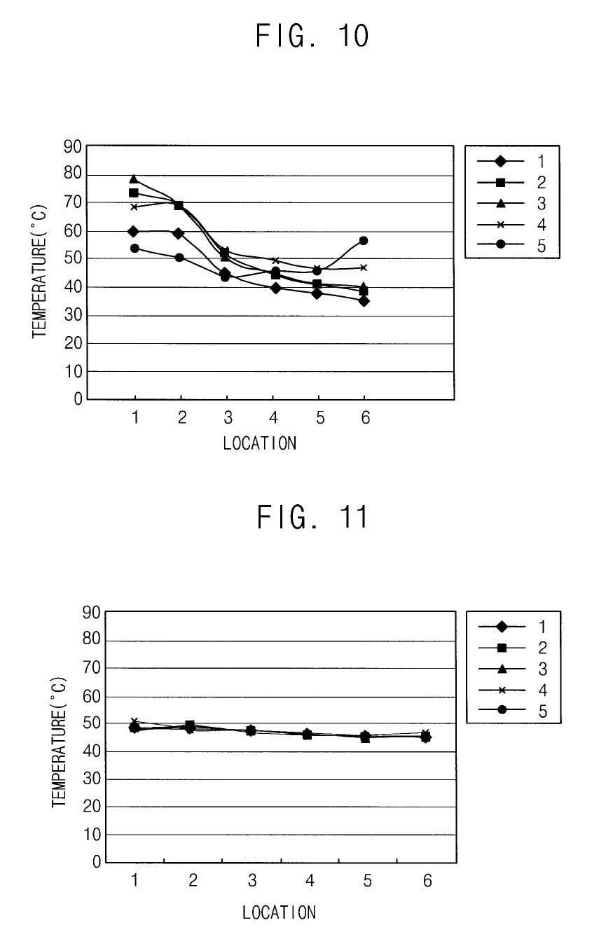

In FIGS. 10 and 11, individual graphs (denoted by the five different symbols in the legend to the right of the graph) represent a row position 1-5 in FIG. 8. Locations 1-6 on the horizontal axes of FIGS. 10 and 11 represent corresponding columns 1-6 of the matrix shown in FIG. 8.

The vertical axis in FIGS. 10 and 11 indicates a maximum temperature (measured in ° C.) in each measurement area of the matrix having the five rows 1-5 and the six columns 1-6.

specifically, referring to FIG. 8, in the display screen, an area of the first row is near the upper peripheral area 12 (FIG. 1) in which the first connection pad 23 of the display panel 5 is formed, and an area of the fifth row is near the lower peripheral area 14. Similarly, an area of the first column is near the left peripheral area 16 in which the second connection pad 25 and the gate connection printed circuit film 95 are disposed, and an area of the sixth column is near the right peripheral area 18 in which the second connection pad 25 is disposed.

Referring to FIGS. 10 and 11, when the heat diffusing member 70 is not disposed on the rear surface of the display panel 5, the display panel 5 has a substantially increased temperature differential as compared to the display device 100 according to an exemplary embodiment of the present invention.

Specifically, referring to FIG. 10, local temperatures increase as the location moves toward the middle portion in a given column, e.g., moving to the third row. A difference between the maximum temperature and the minimum temperature is approximately 10° C. to about 20° C. based upon rows in a given column.

In addition, the local temperatures also increase as the location moves to the left peripheral area 16 and the right peripheral area 18 of the display panel 5 in the same row, e.g., moving toward the first column and the sixth column. A difference between the maximum temperature and the minimum temperature is approximately 5° C. to approximately 40° C. based upon columns in the same row.

In addition, the local temperature of the display screen reaches a maximum temperature of approximately 79° C. (at the third row and the first column), and the local temperature reaches a minimum temperature of approximately 35° C. to approximately 37° C. (at the first row and the sixth column). Thus, the temperature difference is approximately 42° C. to approximately 44° C., which is very large in comparison with the temperature difference associated with an exemplary embodiment of the present invention as shown in FIG. 1.

When the local temperature increases to a temperature of approximately 79° C. at a given specific portion of the display panel 5, the display element 30 is detrimentally heated, and a display quality thereof is deteriorated. In addition, the large temperature difference causes metal wiring of the display panel 5 (such as the power signal line 31 and the driving signal line 35) to exfoliate due to nonuniform thermal expansion, and a lifetime of the display panel 5 is thereby significantly reduced.

FIG. 11 is a graph of temperature versus location illustrating a temperature distribution in the display panel of the display device according to the exemplary embodiment of the present invention shown in FIG. 8.

Referring to FIG. 11, when the heat diffusing member 70 is disposed on the rear surface of the display panel 5, the temperature difference of the display panel 5 is substantially reduced and/or effectively m minimized, due to the heat diffusing member 70 according to an exemplary embodiment of the present invention.

As shown in FIG. 11, the local temperature of the display panel 5 reaches a minimum temperature of approximately 45° C. to approximately 46° C. at a substantially middle portion of the sixth column. The local temperature at the substantially middle portion is relatively low, since the middle portion is farthest from the first connection pad 23 and the second connection pad 25 in comparison with other portions.

However, an area of the sixth column, which is near the second connection pad 25, is not substantially heated due to heat generation of the gate driving section 96, and the local temperature in the area of the sixth column is thereby relatively low.

Further, local temperatures in an area of the first column, an area of the first row and an area of the fifth row of the display panel 5 are all approximately 48° C. to approximately 50° C. Thus, a temperature difference of the display panel 5 is only approximately 2° C. to approximately 5° C.

Thus, the temperature difference of the display panel 5 according to an exemplary embodiment of the present invention is substantially reduced (in comparison with the display device without the heat diffusing member 70 as described in FIG. 10) due to the heat diffusing member 70.

Therefore, a temperature uniformity a display panel according to an exemplary embodiment is substantially improved, and damage caused by hot spots is thereby substantially reduced and/or effectively minimized. In addition, a power transmitting member is entirely disposed in a guide groove formed in a heat diffusing member, and a thickness of the display device according to an exemplary embodiment is substantially reduced. Also, the heat diffusing member enhances a physical rigidity of the display panel, thereby protecting the display panel from damage due to external impact.

According to exemplary embodiments of the present invention as described herein, a display device has advantages which include, but are not limited to, increased effectiveness of temperature control for a self-emitting display panel, and a substantially improved, e.g., simplified, assembly of the display device having the display panel.

The present invention should not be construed as being limited to the exemplary embodiments set forth herein. Rather, these exemplary embodiments are provided so that this disclosure will be thorough and complete and will fully convey the concept of the present invention to those skilled in the art.

While the present invention has been particularly shown and described with reference to exemplary embodiments thereof, it will be understood by those of ordinary skill in the art that various changes in form and details may be made therein without departing from the spirit or scope of the present invention as defined by the following claims.

What is claimed is:

1 A display device comprising:
a base substrate having an upper surface and a lower surface opposite the upper surface;
a power input part disposed in the upper surface of the base substrate;
a power signal line electrically connected to the power input part;
a display element electrically connected to the power signal line and which generates light based on a power signal transmitted via the power input part; and
a heat diffusing member disposed on the lower surface of the base substrate, the heat diffusing member having a guide groove.

2. The display device of claim 1, further comprising a power transmitting member electrically connected to the power input part and disposed in the guide groove.

3. The display device of claim 2, wherein the heat diffusing member comprises:
a first surface facing the lower surface of the base substrate; and
a second surface opposite the first surface, wherein the guide groove is formed in the second surface of the heat diffusing member.

4. The display device of claim 3, wherein a depth of the guide groove in the second surface of the heat diffusing member is smaller less than a thickness of the heat diffusing member.

5. The display device of claim 3, wherein a depth of the guide groove is one of equal to a thickness of the thickness of the power transmitting member and greater than the thickness of the power transmitting member.

6. The display device of claim 2, wherein the heat diffusing member further comprises a graphite plate.

7. The display device of claim 2, wherein the heat diffusing member further comprises a metal plate.

8. The display device of claim 3, further comprising an adhesive layer interposed between the lower surface of the base substrate and the first surface of the heat diffusing member.

9. The display device of claim 3, further comprising a receiving frame configured to receive the display panel, the power transmitting member and the heat diffusing member, wherein the receiving frame is in contact with the second surface of the heat diffusing member.

10. The display device of claim 1, wherein
the power signal comprises a driving voltage and a common voltage, and
the display element comprises:
a first electrode to which the driving voltage is applied;
a second electrode facing the first electrode and to which the common voltage is applied, the second electrode facing the first electrode; and
an organic light-emitting layer interposed between the first electrode and the second electrode to generate light by using a current flowing between the first electrode and the second electrode.

11. The display device of claim 10, wherein the power signal line comprises:
a driving voltage line which transmits the driving voltage to the first electrode; and
a common voltage line which transmits the common voltage to the second electrode.

12. The display device of claim 11, wherein the power transmitting member comprises:
at least one driving voltage transmitting member transmitting the driving voltage; and
at least one common voltage transmitting member transmitting the common voltage.

13. The display device of claim 12, wherein the guide groove comprises:
a first groove in which the driving voltage transmitting member is disposed; and
a second groove in which the common voltage transmitting member is disposed.

14. The display device of claim 13, wherein the power input part comprises:
a first connection pad connecting the driving voltage line to the driving voltage transmitting member; and
a second connection pad connecting the common voltage line to the common voltage transmitting member.

15. The display device of claim 14, wherein
the driving voltage transmitting member extends outward from the heat diffusing member through the first opening to connect to the first connection pad; and
the common voltage transmitting member extends outward from the heat diffusing member through the second opening to connect to the second connection pad.

16. The display device of claim 14, wherein the display panel further comprises:
a driving signal line which transmits a driving signal which controls the driving voltage; and
a driving element connected to the driving signal line and the driving voltage line to transmit the driving voltage to the first electrode based on the driving signal.

17. The display device of claim 16, further comprising a driving module comprises:
a driving substrate which outputs the driving signal; and
a connection printed circuit film connecting the driving substrate to the driving signal line.

18. The display device of claim 17, wherein
the driving voltage transmitting member is connected to a driving voltage connector formed on the driving substrate,
the driving voltage transmitting member receives the driving voltage through the driving substrate via the driving voltage connector,
the common voltage transmitting member is coupled to a common voltage connector formed on the driving substrate, and
the driving voltage transmitting member receives the common voltage through the driving substrate via the common voltage connector.

19. The display device of claim 10, wherein
the display panel further comprises a display plate connected to the base substrate to surface the base substrate,
the display plate covers the display element.
